(19) United States
(12) Patent Application Publication
(10) Pub. No.: US 2025/0089284 A1
(43) Pub. Date: Mar. 13, 2025

(54) STRUCTURE AND METHOD TO PROVIDE DIELECTRIC LAYER HAVING PLURALITY OF RECESSES WITH DIFFERENT DEPTHS

(71) Applicant: GlobalFoundries U.S. Inc., Malta, NY (US)

(72) Inventors: Johnatan Avraham Kantarovsky, South Burlington, VT (US); Michael J. Zierak, Colchester, VT (US); Santosh Sharma, Austin, TX (US); Mark D. Levy, Williston, VT (US); Steven J. Bentley, Menands, NY (US)

(21) Appl. No.: 18/243,910

(22) Filed: Sep. 8, 2023

(51) Int. Cl. H01L 29/66; H01L 29/20; H01L 29/40; H01L 29/417; H01L 29/778

(52) U.S. Cl. CPC H10D 30/015; H10D 30/475; H10D 62/8503; H10D 64/117; H10D 64/258

(57) ABSTRACT

A structure according to the disclosure includes a dielectric layer over a substrate and horizontally between a gate terminal and a source/drain (S/D) terminal. The dielectric layer has a first surface proximal to the substrate and a second surface opposite the first surface. The dielectric layer has a plurality of recesses in the second surface. At least some of the plurality of recesses have different depths. A conductive field plate includes a metal layer on the second surface and within the plurality of recesses. The conductive field plate is electrically isolated from the gate terminal and the S/D terminal.

### STATEMENT REGARDING FEDERAL RIGHTS

This invention was made with government support under DMEA GAN ON SIC Contract No. HQ0727790700 awarded by the United States Defense Microelectronics Activity (DMEA). The government has certain rights in the invention.

### BACKGROUND

The present disclosure relates to transistors and, more particularly, to embodiments of a structure including a structure and method for a III-V integrated circuit in which a dielectric layer includes a plurality of recesses.

III-V semiconductor devices, such as high electron mobility transistors (HEMTs) and metal-insulator-semiconductor HEMTs (MISHEMTs), have emerged as a leading technology for power switching, radio frequency (RF) and millimeter wave (mmWave) (e.g., 3-300 GHz) wireless applications. One challenge associated with HEMT structures is that the electric field within the III-V semiconductor substrate may be irregularly shaped, e.g., the peak electric field strength may be in close proximity to sensitive components. In some structures, the HEMT may have its strongest electric field near the gate of the transistor, which may negatively affect the p-type gallium nitride (pGaN) material within the gate.

### SUMMARY

All aspects, examples and features mentioned below can be combined in any technically possible way.

An aspect of the disclosure provides a structure including a dielectric layer over a substrate and horizontally between a gate terminal and a source/drain (S/D) terminal, wherein the dielectric layer has a first surface proximal to the substrate and a second surface opposite the first surface, wherein the dielectric layer has a plurality of recesses in the second surface, and wherein at least some of the plurality of recesses have different depths; and a conductive field plate including a metal layer on the second surface and within the plurality of recesses, wherein the conductive field plate is electrically isolated from the gate terminal and the S/D terminal.

An aspect of the disclosure provides a structure including a pair of source/drain (S/D) terminals over a substrate, the substrate including a III-V semiconductor material; a gate terminal over the substrate and horizontally between the pair of S/D terminals; a dielectric layer over the substrate and horizontally between the gate terminal and one of the pair of S/D terminals, wherein the dielectric layer has a first surface proximal to the substrate and a second surface opposite the first surface, wherein the dielectric layer has a plurality of recesses in the second surface, and wherein at least some of the plurality of recesses have different depths; and a conductive field plate including a metal layer on the second surface and within the plurality of recesses, wherein the conductive field plate is electrically isolated from the gate terminal and the pair of S/D terminals.

An aspect of the disclosure relates to a method including forming a dielectric layer over a substrate and horizontally between a gate terminal and a source/drain (S/D) terminal, wherein the dielectric layer has a first surface proximal to the substrate and a second surface opposite the first surface, wherein the dielectric layer has a plurality of recesses in the second surface, and wherein at least some of the plurality of recesses have different depths; and forming a conductive field plate including a metal layer on the second surface and within the plurality of recesses, wherein the conductive field plate is electrically isolated from the gate terminal and the S/D terminal.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a cross-sectional view of a structure in plane X-Z, according to embodiments of the disclosure.

FIG. 2 shows a plan view of the structure in plane X-Y according to embodiments of the disclosure.

FIG. 3 shows a first cross-sectional view of a structure in plane X-Z, according to further embodiments of the disclosure.

FIG. 4 shows a second cross-sectional view of a structure in plane X-Z, according to further embodiments of the disclosure.

FIG. 5 shows a plan view of the structure in plane X-Y according to further embodiments of the disclosure.

FIGS. 6-9 show cross-sectional views of a method of forming a structure, according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure include a structure, e.g., for a III-V integrated circuit, which may be included and/or used together with gallium nitride high electron mobility transistors (HEMTs). More particularly, embodiments of the disclosure include a structure with a dielectric layer over a substrate and horizontally between a gate terminal and a source/drain (S/D) terminal. The dielectric layer has a first surface proximal to the substrate and a second surface opposite the first surface. The dielectric layer has a plurality of recesses in the second surface. At least some of the plurality of recesses have different depths. A conductive field plate includes a metal layer on the second surface and within the plurality of recesses. The conductive field plate is electrically isolated from the gate terminal and the S/D terminal. By electrically coupling the field plate to the source terminal, an electric field within the substrate thereunder may change in profile and intensity. The recesses of the dielectric layer, which have varying depths, cause the metal layer to be closer to the substrate in selected locations. Thus, the metal layer may have a greater effect on electric field strength within the substrate within the deeper recesses and conversely a weaker effect in shallower recesses, and a still weaker effect in any non-recessed regions. A manufacturer may provide a larger number and/or larger sized recesses in areas of a device where weaker electric fields are desired in the substrate. Conversely, fewer or smaller sized recesses, and/or non-recessed regions of the dielectric layer, may be provided where more electric field strength is desired in the substrate.

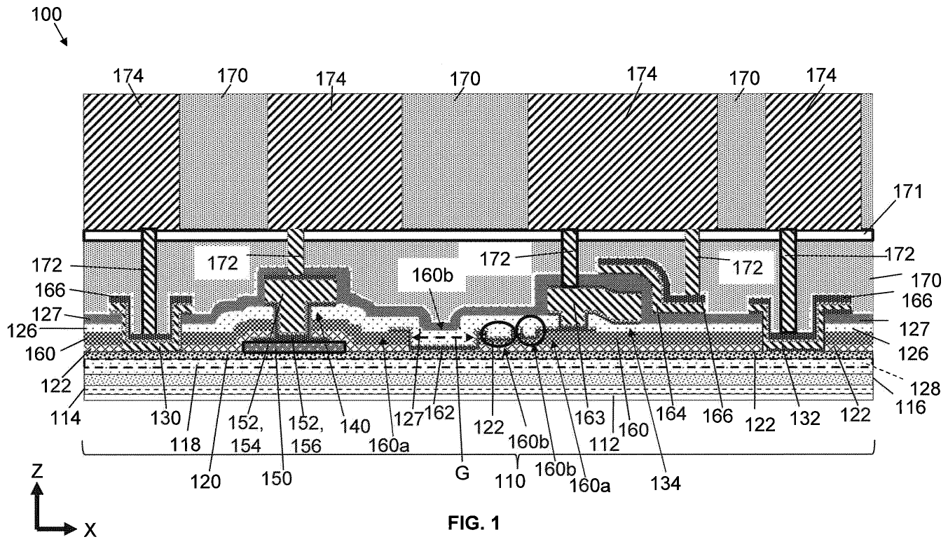

FIG. 1 shows a cross-sectional view of a structure 100 for a III-V integrated circuit. Structure 100 includes a high electron mobility transistor (HEMT) 110. HEMT 110 may be over a semiconductor layer 112 (e.g., silicon (Si) or silicon germanium (SiGe). HEMT 110 can be above multiple epitaxially grown semiconductor layers on a semiconductor substrate 114. Semiconductor substrate 114 may be a semiconductor material particularly suited to HEMT 110, e.g., it may be a superlattice transition layer having several periodic layers of III-V semiconductor materials. Further materials on semiconductor substrate 114 may provide a gallium nitride (GaN) stack. Epitaxially grown semiconductor layers on substrate 114 suitable to provide a GaN stack can include, for example: an optional buffer layer 116 on the top surface of semiconductor substrate 114; a channel layer 118 on buffer layer 116; and a barrier layer 120 on channel layer 118. These epitaxial grown semiconductor layers can be, for example, III-V semiconductor layers. Those skilled in the art will recognize that a III-V semiconductor refers to a compound obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP).

Optional buffer layer 116 can be employed to facilitate growth of channel layer 118 and to provide for lattice constants of substrate 114 below and channel layer 118 above. Buffer layer 116 can be doped or undoped. Optionally, buffer layer 116 can be carbon doped. Barrier layer 120 can have a band gap that is wider than the bandgap of channel layer 118 for the device channel. Those skilled in the art will recognize that the barrier and channel materials can be selected so that a heterojunction is formed at the interface between the two layers, thereby resulting in the formation of a two-dimensional electron gas (2DEG) region 128 in channel layer 118 (see dashed box). This 2DEG region 128 in channel layer 118 can provide the conductive pathway for the drifting of charges between the source and the drain.

In some embodiments, buffer layer 116 could be a carbon-doped gallium nitride (C-GaN) buffer layer or a buffer layer of any other material suitable for use as a buffer layer of a HEMT or MISHEMT. Channel layer 118 could be a gallium nitride (GaN) layer or a III-V semiconductor channel layer made of any other III-V semiconductor compound suitable for use as a channel layer in a HEMT or MISHEMT. Hence, channel layer 118 may also be referenced as a “GaN channel layer” herein. Barrier layer 120 could be an aluminum gallium nitride (AlGaN) barrier layer or a barrier layer of any other material suitable for use as a barrier layer in a HEMT or MISHEMT. Hence, barrier layer 120 may also be referenced as an “AlGaN barrier layer” herein. For purposes of illustration, the figures and the description depict the epitaxially grown layers (e.g., buffer layer 116; channel layer 118; and barrier layer 120) as being single layered structures (i.e., comprising one layer of buffer material, one layer of channel material and one layer of barrier material). However, it should be understood that, alternatively, any one or more of the epitaxially grown layers could be multi-layered structures (e.g., comprising multiple sub-layers of different buffer materials, multiple sub-layers of different III-V semiconductor channel materials and/or multiple sub-layers of different barrier materials).

One or more passivation layers may be over barrier layer 120. In the example shown, two passivation layers 122, 126 are shown with a dielectric layer 160 (also known as a “field dielectric layer” by reference to its use in field plate structures) located therebetween. Passivation layers 122, 126 may include one or more layers of any appropriate passivation material such as but not limited to silicon nitride (Si₃N₄) and/or silicon oxide (SiOₓ). For purposes of illustration, the figures and the description depict passivation layers 122, 126 as being single layered structures. However, it should be understood that, alternatively, one or both passivation layers 122, 126 could be multi-layered structures, e.g., comprising multiple sub-layers of different passivation materials. Dielectric layer 160 also may function partially as an etch stop layer between passivation layers 122, 126 to protect the lower passivation layer 122 during etching processes. Dielectric layer 160 may include any currently known or later developed dielectric based etch stop layer(s). A spacer layer 127 (e.g., one or more other dielectric substances for providing additional electrical and physical isolation) may cover passivation layer 126 to help physically and electrically isolate various portions of HEMT 110 from conductors and/or other materials formed thereon.

HEMT 110 is illustrated as an enhancement mode HEMT (“EM HEMT”) but in alternative implementations (e.g., by the omission of a pGaN layer in a gate structure 140 and placing gate structure 140 immediately adjacent barrier layer 120) may be depletion mode DEMT (“DM HEMT”). A depletion mode HEMT 110 is depicted in structure 100 solely as an example. “Enhancement mode” indicates HEMT 110 is typically in an off-state and requires a positive voltage (referred to as a “threshold voltage”) to be applied to a gate thereof to turn it on, i.e., enhance/allow electron flow through 2DEG region 128 and channel layer 118. “Depletion mode” indicates HEMT 110 is typically in an on-state and requires a negative voltage (referred to as a “pinch-off voltage”) to be applied to a gate thereof to turn it off, i.e., to deplete electron flow through 2DEG region 128 in channel layer 118.

HEMT 110 in an example includes a first source/drain (S/D) terminal 130 (illustrated as a source terminal), a second S/D terminal 132 (illustrated as a drain terminal) and, optionally, a field plate gate 134 between first S/D terminal 130 and second S/D terminal 132. In addition, HEMT 110 includes a gate structure 140 between first S/D terminal 130 and field plate gate 134, but it is understood that gate structure 140 alternatively may be between second S/D terminal 132 and field plate gate 134. In any case, gate structure 140 and field plate gate 134 (where included) each are located horizontally between S/D terminals 130, 132. Field plate gate 134, wherein included, may be closer to second S/D terminal 132 (or first S/D terminal 130 in other embodiments) than gate structure 140. Field plate gate 134 may be within structure 100 between gate structure 140 and one S/D terminal 130, 132 to increase the breakdown voltage of HEMT 110, which may be particularly desirable for power amplifiers or similar circuits. Gate structure 140 may include a p-type GaN (pGaN) layer 150 underneath a metallic layer 152. In this case, gate structure 140 may also be referenced herein as a “pGaN gate.” In certain embodiments, pGaN layer 150 is in direct contact with metallic layer 152, i.e., there are no intervening layers. Metallic layer 152 may include, for example, a metal or metal alloy 154 such as but not limited to titanium aluminum or titanium nitride, and an ohmic contact 156 such as titanium nitride (TiN) or any other appropriate ohmic contact material. pGaN layer 150 may include, for example, p-type doped gallium nitride. The p-type dopant may include any appropriate p-type dopant for GaN such as but not limited to magnesium, zinc, cadmium and carbon. The source and drain terminals 130, 132 may be ohmic contact source/drain terminals at the metal-semiconductor junction at the bottom of source/drain openings. Thus, source/drain terminals 130, 132 can include one or more layers of ohmic metal or metal alloys. For example, the source/drain terminals 130, 132 could include layers of titanium (Ti)/aluminum (Al)/titanium nitride (TiN), layers of Ti/Al/Ti/gold (Au) or alternating layers of molybdenum (Mo) and Au.

Field plate gate 134, when included in structure 100, may have a composition different than a composition of gate structure 140. Field gate plate 134 may be formed above a dielectric layer 160 which has a metal layer 162 thereon. Metal layer 162 may include, for example, titanium nitride or titanium aluminum. In cases where field gate plate 134 is not included, dielectric layer 160 and metal layer 162 nonetheless may be located in the same position but without field gate plate 134 thereover. In such cases, structure 100 may include a metallic contact that extends vertically directly to metal layer 162 (e.g., contact(s) 172 discussed herein may extend vertically from wire(s) 174 to metal layer 162).

Dielectric layer 160 may be subdivided into a group of non-recessed regions 160a and recessed regions having recesses 160b. Each recess 160b may be horizontally between a respective pair of non-recessed regions 160b. Metal layer 162 may extend continuously over non-recessed regions 160a and recesses 160b of dielectric layer 160, such that metal layer 162 covers the upper surfaces and sidewalls of dielectric layer 160 above channel layer 118. Hence, the composition of metal layer 162 may be uniform and it may be formed by way of conformal deposition and/or other techniques of forming metal layers on exposed surfaces and sidewalls of a previously formed material. Two or more recesses 160b may have distinct depths within dielectric layer 160. At least two recesses 160b may have distinct lengths (e.g., along the X-axis) as discussed herein between respective pairs of non-recessed regions 160a. Similarly, two or more non-recessed regions 160a may have distinct lengths between respective pairs of recesses 160b, e.g., to further vary the position of recesses 160b and thus increase or decrease the effect that field plate gate 134 will have on electric fields within channel layer 118 at various locations.

During operation, recesses 160b of dielectric layer 160 may counteract (and thus shape) the electric field strength within channel layer 118 of HEMT 110. For example, sharp corners/edges of gate structure 140 can provide a strong electric field that can change functions of HEMT 110 over time, e.g., change a threshold voltage and/or saturation currents. Field plate gates 134, where included, provides a metal-insulator-semiconductor (MIS) capacitor that reduces field crowding at an edge of gate structure 140. Field plate gate 134 also supports using high voltage without using extensive amounts of GaN, which can be expensive. Recesses 160b can be formed in a variety of shapes and sizes to further control the effect of field plate gate 134 on the electric field within channel layer 118.

The thickness of dielectric layer 160 may be non-uniform, and more specifically, dielectric layer 160 optionally may have a different thickness within each recess 160b. Recesses 160b with thicker portions of dielectric layer 160 may have a weaker effect on the electric field strength therebelow, whereas recesses 160b with thinner portions of dielectric layer 160 may have a stronger effect on the electric field strength therebelow. In some implementations, dielectric layer 160 may include a gap G horizontally between two non-recessed regions 160a, e.g., a portion of dielectric layer 160 material may be completely etched away. That is, one or more recesses 160b may extend into the passivation layer 122 below. However, it should be emphasized that the none of the recesses 160b should extend completely through the dielectric layer 160 and passivation layer 122 to the barrier layer 120 below so that the metal layer 162 remains physically separated and electrically isolated from the barrier layer 120. In such cases metal layer 162 may nonetheless extend continuously through gap G from one non-recessed region 160b to another. The differences in thickness may be achieved, e.g., by multiple masking processes to cover certain recesses 160b while others are etched, through etch loading techniques (i.e., using smaller openings in an etch mask in certain areas to remove smaller amounts of dielectric material), and/or other techniques to control the thickness of a previously formed dielectric material. The interaction between metal layer 162 and channel layer 118 can be controlled further, e.g., by reducing the depth of each recess 160b to reduce the effects on channel layer 118 (or vice versa), increasing the length of each recess 160b to increase the effects on channel layer 118 (or vice versa), etc. In the example of FIG. 1, structure 100 shows three recesses 160b each having a distinct length, depth, and different dielectric layer 160 thickness, but this is not necessarily required. Regardless of how recesses 160b are shaped, non-recessed regions 160a may have a uniform height over channel layer 118, e.g., approximately five-hundred nanometers to approximately one-thousand nanometers.

Field plate gate 134, where included, have a conductor 163 electrically coupled to a field plate 164 through one or more overlying metal wires and contacts (e.g., certain contacts 172 and metal wires 174 discussed herein). Field plate 164 may include, for example, titanium nitride (TiN) or other refractory metal materials and conductor 163 may include similar materials (for example, TiN or titanium aluminum (TiAl)) and/or other types of conductive metals. To aid in the coupling of certain materials such as S/D terminals 130, 132, conductor 163, and/or field plate 164, to conductive materials formed thereon, a conductive film 166 (e.g., copper (Cu), aluminum (Al), and/other thin layers of metal) may be formed on S/D terminals 130, 132, conductor 163, and/or field plate 164 by conformal deposition or similar techniques to form conductive metal(s).

Structure 100 may include a variety of interconnects depending on the application thereof. Interconnects can be provided in any middle-of-line and/or back-end-of-line interlayer dielectric (ILD) layers 170 using known techniques. ILD layers 170 are shown in two vertical positions, it will be recognized by those with skill in the art that any number of ILD layers 170 may be provided. One or more barrier films 171 (e.g., nitride insulators and/or other dielectric materials) may be vertically between ILD layers 170 to vertically separate each layer and/or to prevent underlying materials from being affected during the processing of other materials, layers, etc. thereon. Interconnects may include any required contacts or vias (collectively “contacts” hereafter) 172 and metal wires 174. Each contact 172 may include any currently known or later developed conductive material configured for use in an electrical contact, e.g., tungsten (W). Contacts 172 may additionally include refractory metal liners (not shown) positioned alongside ILD layer 170 to prevent electromigration degradation, shorting to other components, etc. Additional conductive materials (e.g., conductive film(s) 166) as discussed herein may be located beneath each contact 172 to improve electrical coupling(s) from contact(s) 172 to various portions of structure 100. Metal wires 174 may include any appropriate conductors such as aluminum or copper. Metal wires 174 may also include refractory metal liners (not shown) positioned alongside ILD layer 170 to prevent electromigration degradation, shorting to other components, etc. According to an example, structure 100 also includes contacts 172 interconnecting conductor 163 to field plate 164 of field plate gate 134 through a metal wire 174. As discussed elsewhere herein, contact(s) 172 may extend vertically from metal wire 174 to metal layer 162 in the case where field plater gate 134 is omitted.

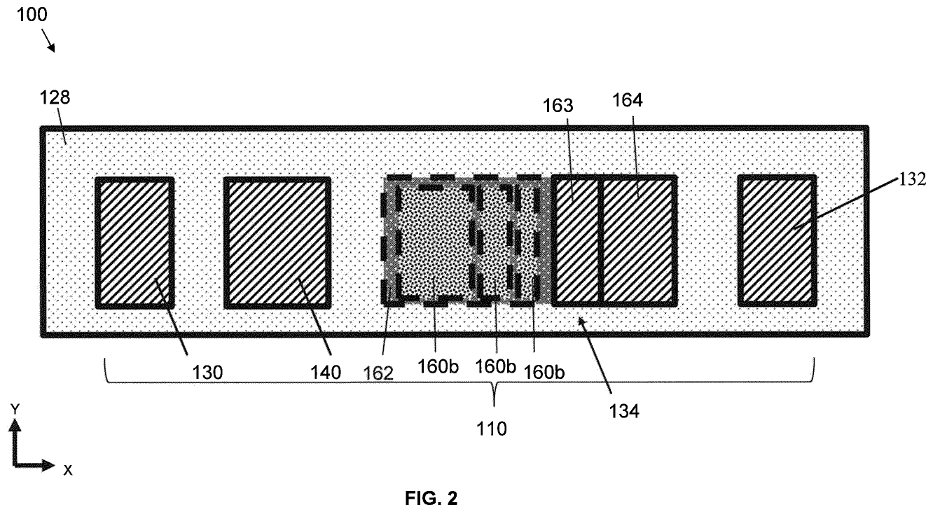

Referring to FIGS. 1 and 2 together, in which FIG. 2 provides a plan view of FIG. 1 in plane X-Y, recesses 160b of dielectric layer 160 optionally may have substantially uniform widths (e.g., measured along Y-axis as shown) but varying lengths (e.g., measured along X-axis as shown). In this arrangement, recesses 160b may be substantially rectangular in plane X-Y, and thus may have substantially uniform effects on the electric field within channel layer 118. In other words, larger recesses 160b may oppose the electric field strength within channel layer 118 than smaller recesses 160b. Although the larger of recesses 160b are illustrated as distal to second S/D terminal 132 (e.g., the drain) and the smaller of recesses 160b are illustrated as proximal to second S/D terminal 132 of HEMT 110, they may be in different positions in other implementations.

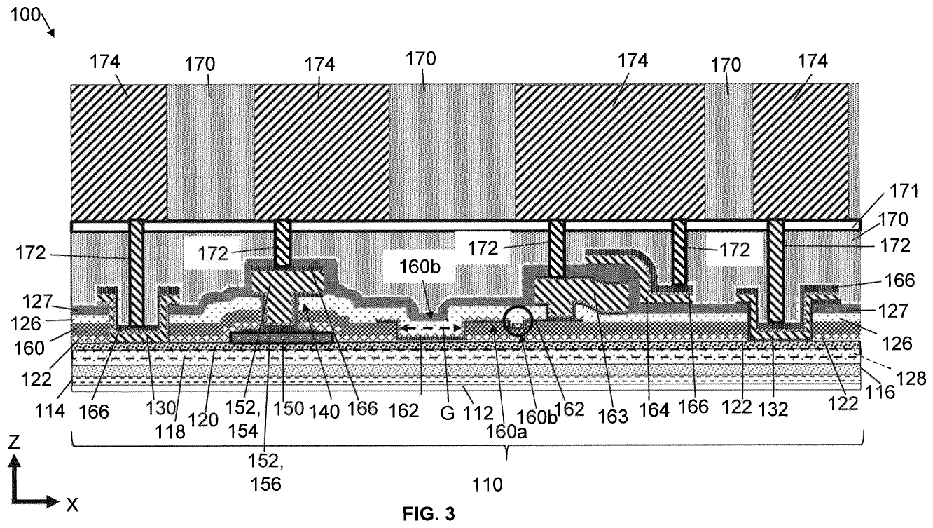

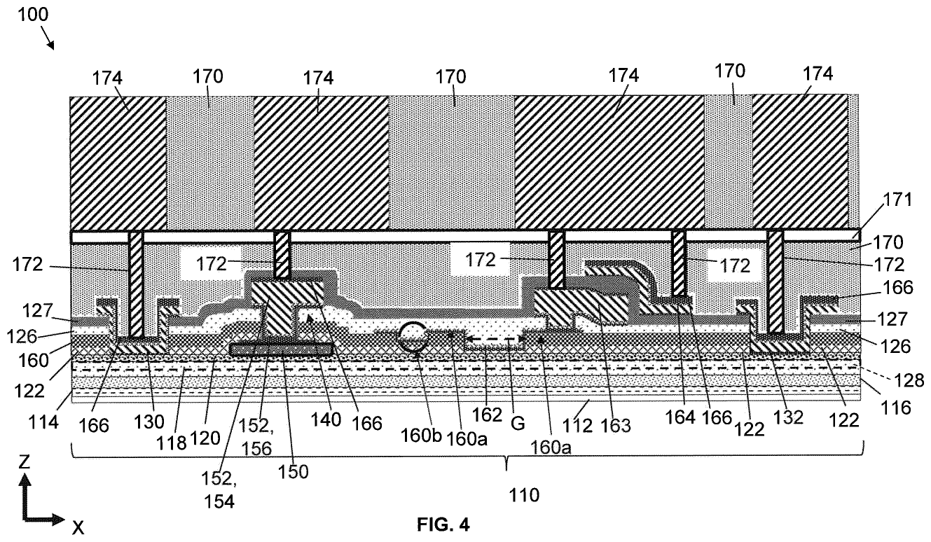

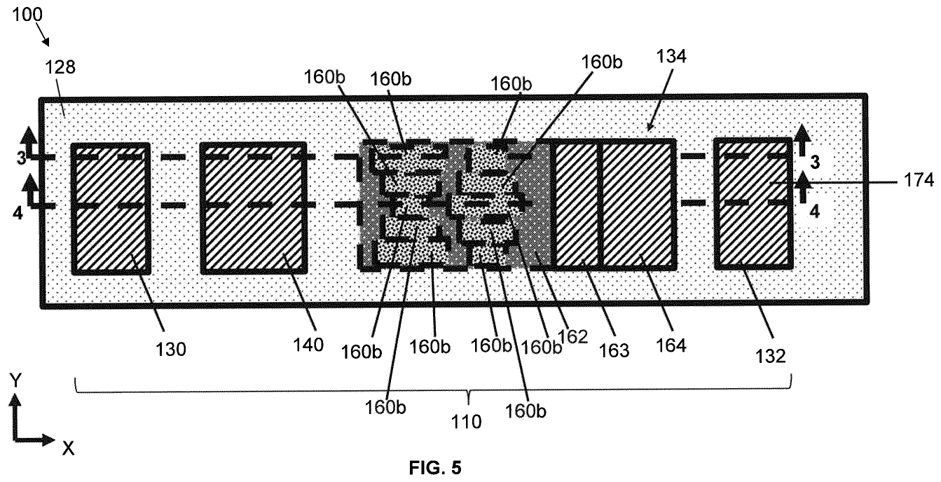

Referring now to FIGS. 3-5, in which FIGS. 3 and 4 provide two cross-sectional views along lines 3-3 and 4-4 of FIG. 5, further implementations of structure 100 may provide a variety of metal layer 162 configurations to further influence the electric field strength within channel layer 118. Along view line 3-3, non-recessed regions 160a and recesses 160b may have approximately the same pattern depicted in FIGS. 1 and 2. That is, the largest and deepest recess 160b is closest to gate structure 140 and first S/D terminal 130 whereas the smallest and shallowest recess 160b is closest to second S/D terminal 132. However, structure 100 may include different arrangements of non-recessed regions 160a and recesses 160b in dielectric layer 160 and metal layer 162 along different cross-sections. In the view of structure 100 along line 4-4, for example, non-recessed regions 160a and recesses 160b may have the opposite pattern from that depicted along line 3-3. That is, the largest and deepest recess 160b is closest to second S/D terminal 132 whereas the smallest and shallowest recess 160b is closest to gate structure 140 and first S/D terminal 130. As indicated in FIG. 5, other cross-sections of dielectric layer 160 may include a set of recesses 160b that may be approximately equal in length between and/or depth below non-recessed regions 160a. Dielectric layer 160 in the example of FIG. 4 includes an hourglass pattern of recesses 160b adjacent an inverted hourglass pattern of recesses 160b, but a variety of other arrangements and/or recess 160b shapes are also possible. For instance, some embodiments of structure 100 may include a set of recesses 160b that, as a formation, taper from largest length to smallest length along one orientation (e.g., top to bottom along Y-axis), which may be adjacent another set of recesses 160b that, as a formation, taper from largest to smallest along the opposite orientation (e.g., bottom to top along Y-axis). Some or more of recesses 160b may have distinct depths, as shown in FIGS. 3 and 4 and discussed elsewhere herein. Other sets of shapes, including non-complementary arrangements, are also possible based on the intended effect(s) of metal layer 162 on electric fields within channel layer 118. For example, increasing the width and/or depth of each recess 160b may help to modulate electric fields within channel layer 118 at the corners and/or edges of semiconductor material thereof, but may increase channel capacitance in the same region(s).

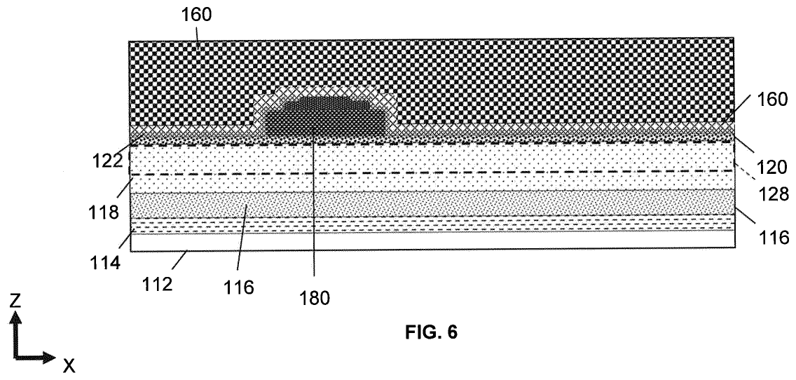

Turning to FIG. 6, embodiments of the disclosure provide methods to form structure 100, and an example of such a method is discussed herein. Substrate 114 (e.g., a GaN stack) may be formed or provided according to any currently known or later developed method to provide substrate material(s) discussed herein. A GaN layer 180 (e.g., precursor material for gate structure 140 discussed herein) may be formed on substrate 114 by growth and/or deposition followed by etching to create GaN layer 180 over only a portion of substrate 114. With GaN later in place, pGaN layer 150 then may be formed on substrate 114 and GaN layer 180, such that portions of pGaN layer 150 cover the upper surface(s) and sidewalls of GaN layer 180. Dielectric layer 160, or other dielectric material, can then be formed to cover pGaN layer 150 as well as all materials located therebelow.

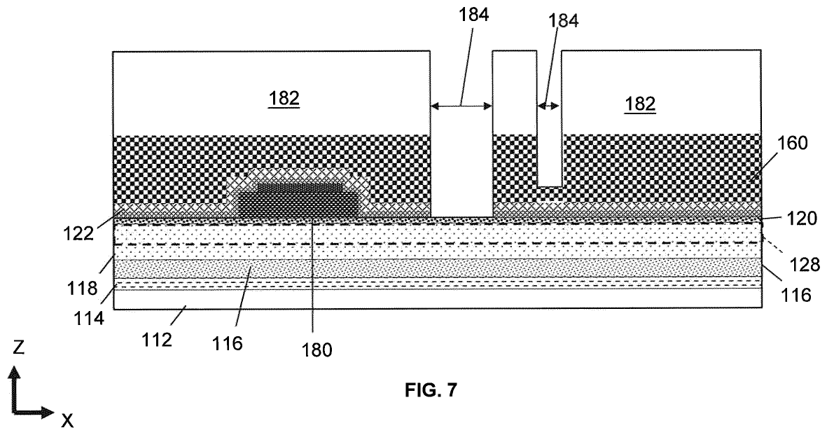

FIG. 7 depicts initial steps to begin forming different regions of field plate gate 134. A photoresist layer 182 (or other masking material) can be formed on dielectric layer 160 (or other dielectric material). Photoresist layer 182 may include openings 184 of varying size, e.g., to control the eventual size and shape of recess(es) 160b (FIGS. 1-5) discussed herein. Differences in the size of each opening 184 may affect the rate at which portions of dielectric layer 160 therebelow are removed, e.g., via etching. Larger openings 184 may enable removing all of dielectric layer 160 within such openings 184, as well as any portion(s) of pGaN layer 150 also located beneath dielectric layer 160. Openings 184 of smaller size, in the same instance of removing exposed portions of dielectric layer 160, may cause only a portion of dielectric layer 160 thereunder to be removed. Thus, the same process to remove dielectric layer 160 material may produce different size and different depth openings within dielectric layer 160. In further implementations, several photoresist layers 182 may be used in succession, and each may have different openings 184 to remove different amounts of dielectric layer 160 (and/or pGaN layer 150) material by successive instances of etching and/or other removal techniques.

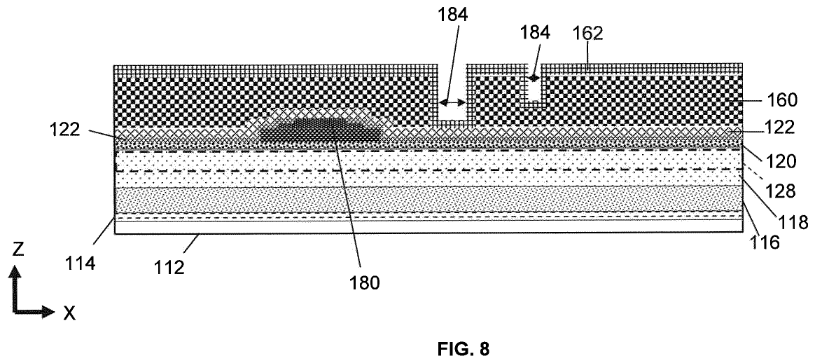

Referring now to FIG. 8, further processing includes the removing of photoresist layer(s) 182 (e.g., by stripping away of photoresist material) and forming of metal layer 162 on dielectric layer 160 and within any openings formed therein. Metal layer 162 may be formed, e.g., by deposition of metallic material(s), e.g., titanium nitride (TiN) or other currently known or later developed conductors suitable for use within field plate gate 134. TiN in particular is considered to be a “refractory metal” and other refractory metal compounds (e.g., those used conventionally for lining of metal wires or vias) may be used such that the forming of metal layer 162 may occur simultaneously with the forming of such liners. As shown, metal layer 162 may cover the top surface of dielectric layer 160 (or other dielectric material(s) in its place), as well as openings therein to completely cover any exposed surfaces, sidewalls, etc., of dielectric layer 160, as well as any portions of substrate 114 and/or pGaN layer 150 previously exposed from removal processes described herein.

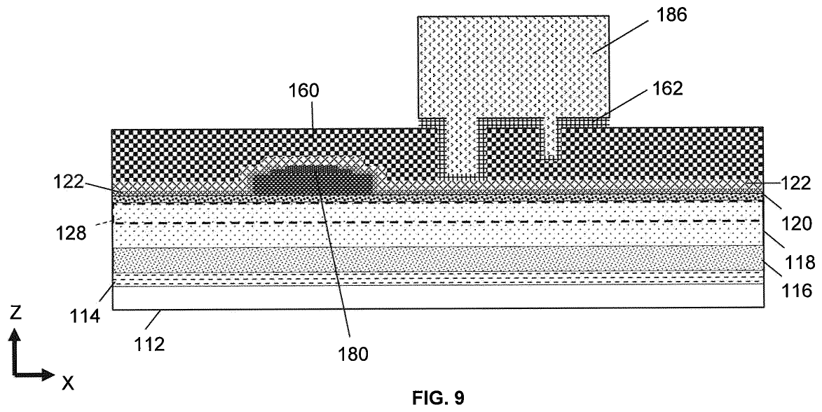

FIG. 9 depicts further processing, in which a recess photoresist layer 186 is formed on portions of metal layer 162 that are within the openings of dielectric layer 160, as well as over nearby surfaces of dielectric layer 160. Recess photoresist layer 186 may be shaped to have substantially the same width as the eventual length of metal layer 162 in structure 100, i.e., no portion of recess photoresist layer 186 is located above GaN layer 180. With recess photoresist layer 186 in place, other portions of metal layer 162 not covered by recess photoresist layer 186 may be removed by downward and/or selective etching techniques, such that metal layer 162 is retained below recess photoresist layer 186 but removed elsewhere. In subsequent processing, recess photoresist layer 186 may be removed (e.g., by stripping or other processes suitable to remove photoresist material(s), and remaining portions of structure 100 may be formed substantially in accordance with conventional techniques to provide HEMT(s), e.g., repeated instances of depositing dielectric and/or conductive materials, removing portions of such materials, etc., to yield substrate 114 as discussed herein.

Embodiments of the disclosure provide technical and commercial advantages, examples of which are discussed herein. By including dielectric layer 160 with stepped recesses 160b, and metal layer 162 therein, designers and/or operators of a device can manipulate the electric field strength in sensitive areas of channel layer 118. Specifically, metal layer 162 as discussed herein is operable to smoothen the electric field strength in along edges, corners, etc., of a semiconductor material to further manipulate breakdown voltage and/or other properties of HEMT 110. Manipulating the electric field of an HEMT structure in this manner, in turn, may accommodate larger operating voltages and/or may improve device reliability without increasing the surface area needed to provide structure 100 and HEMT 110 therein. Moreover, methods of forming structure 100 with dielectric layer 160 and metal layer 162 can easily be integrated into conventional processes to form an HEMT structure.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a dielectric layer over a substrate and horizontally between a gate terminal and a source/drain (S/D) terminal, wherein the dielectric layer has a first surface proximal to the substrate and a second surface opposite the first surface, wherein the dielectric layer has a plurality of recesses in the second surface, and wherein at least some of the plurality of recesses have different depths; and
a conductive field plate including a metal layer on the second surface and within the plurality of recesses, wherein the conductive field plate is electrically isolated from the gate terminal and the S/D terminal.

2. The structure of claim 1, wherein the depths of the recesses decrease between the gate terminal and the S/D terminal.

3. The structure of claim 1, wherein the metal layer is on sidewalls of at least one of the plurality of recesses.

4. The structure of claim 1, wherein at least one of the plurality of recesses extends completely through dielectric layer and defines a gap therein.

5. The structure of claim 1, wherein at least two of the plurality of recesses have distinct lengths.

6. The structure of claim 1, wherein the upper surface of the dielectric layer includes at least two segments having distinct lengths between respective pairs of the plurality of recesses.

7. The structure of claim 1, wherein the substrate includes a III-V semiconductor material and is within a high electron mobility transistor (HEMT).

8. A structure comprising:
a pair of source/drain (S/D) terminals over a substrate, the substrate including a III-V semiconductor material;
a gate terminal over the substrate and horizontally between the pair of S/D terminals;
a dielectric layer over the substrate and horizontally between the gate terminal and one of the pair of S/D terminals, wherein the dielectric layer has a first surface proximal to the substrate and a second surface opposite the first surface, wherein the dielectric layer has a plurality of recesses in the second surface, and wherein at least some of the plurality of recesses have different depths; and
a conductive field plate including a metal layer on the second surface and within the plurality of recesses, wherein the conductive field plate is electrically isolated from the gate terminal and the pair of S/D terminals.

9. The structure of claim 8, wherein the depths of the recesses decrease between the gate terminal and the S/D terminal.

10. The structure of claim 8, wherein the metal layer is on sidewalls of at least one of the plurality of recesses.

11. The structure of claim 8, wherein at least one of the plurality of recesses extends completely through dielectric layer and defines a gap therein.

12. The structure of claim 8, wherein at least two of the plurality of recesses have distinct lengths.

13. The structure of claim 8, wherein the upper surface of the dielectric layer includes at least two segments having distinct lengths between respective pairs of the plurality of recesses.

14. The structure of claim 8, wherein the substrate, the gate terminal, and the pair of S/D terminals define portions of a high electron mobility transistor (HEMT).

15. A method comprising:
forming a dielectric layer over a substrate and horizontally between a gate terminal and a source/drain (S/D) terminal, wherein the dielectric layer has a first surface proximal to the substrate and a second surface opposite the first surface, wherein the dielectric layer has a plurality of recesses in the second surface, and wherein at least some of the plurality of recesses have different depths; and
forming a conductive field plate including a metal layer on the second surface and within the plurality of recesses, wherein the conductive field plate is electrically isolated from the gate terminal and the S/D terminal.

16. The method of claim 15, further comprising forming at least two of the plurality of recesses to having decreasing depths between the gate terminal and the S/D terminal.

17. The method of claim 15, further comprising forming the metal layer on sidewalls of at least one of the plurality of recesses.

18. The method of claim 15, wherein forming the dielectric layer includes forming at least one of the plurality of recesses completely through dielectric layer to defines a gap within the dielectric layer.

19. The method of claim 15, wherein forming the dielectric layer includes forming the upper surface to include at least two segments having distinct lengths between respective pairs of the plurality of recesses.

20. The method of claim 15, further comprising forming a high electron mobility transistor (HEMT) by forming the S/D terminal, the gate terminal, and an additional S/D terminal on the substrate, wherein the substrate includes a III-V semiconductor material.
